(19) United States
(12) Patent Application Publication
(10) Pub. No.: US 2023/0041836 A1
(43) Pub. Date: Feb. 9, 2023

(54) THERMAL MANAGEMENT DEVICE AND METHOD OF USE

(71) Applicant: Hamilton Sundstrand Corporation, Charlotte, NC (US)

(72) Inventors: Debabrata Pal, Hoffman Estates, IL (US); Tom A. Utecht, Cherry Valley, IL (US); Craig R. LeGros, Rockford, IL (US)

(73) Assignee: Hamilton Sundstrand Corporation, Charlotte, NC (US)

(21) Appl. No.: 17/962,138

(22) Filed: Oct. 7, 2022

Related U.S. Application Data
(62) Division of application No. 16/788,680, filed on Feb. 12, 2020, now abandoned.

(51) Int. Cl. B64D 13/06

(52) U.S. Cl. CPC B64D 13/06; B64D 2013/0614

(57) ABSTRACT

A system including a thermal management body attached to an electronics equipment, a cavity within the thermal management body storing a coolant, and a cold plate separating the cavity and the electronics equipment.

### BACKGROUND

### Technological Field

The present disclosure relates to electronics thermal management, and more particularly to thermal management of a device during startup.

### Description of Related Art

A variety of devices are known for providing a cooling solution for power electronics. Power electronics devices are usually mounted on a heat spreader or a cold plate or to a heat sink in order to cool them during operation. Typical packaging configuration usually results in a bulky two-dimensional design, which has a relatively high volume, especially for air cooled cases. The aerospace industry demands lightweight and high compactness packaging solutions while also significantly increasing power level requirements. Further, typical configurations require bypass air to cool electronics. However, during startup or other motionless activities, no bypass air is available to provide cooling to electronics.

The conventional methods and systems have generally been considered satisfactory for their intended purpose, but are not appropriate any more when due to an increase in output powers of power electronics devices and volume and/or weight constrains remaining the same. However, there is still a need in the art for a thermal management system that is able to provide an appropriate amount of cooling prior during startup. The present disclosure may provide a solution for at least one of these remaining challenges.

### SUMMARY OF THE INVENTION

An aircraft thermal management system includes a body having a cavity defined by at least a first wall and a second wall, the first wall being in thermal communication with an electronic device, the second wall being in thermal communication with an air flow when the aircraft is airborne, and a fluid positioned within the cavity configured to transfer heat from the first wall and the electronic device to the fluid while transitioning at least some of the fluid from a liquid to a gas, and to transfer heat from the fluid to the second wall and the air flow while transitioning at least some of the fluid from a gas to a liquid. The electronic device can be a bi-directional rectifier.

A series of fins can be located on the outside of the body and protrude into a fan bypass section of an aircraft engine. The body can be attached to an active rectifier. The fluid can be a two-phase coolant, such as a NOVEC coolant. The electronic device can be attached to an engine fan casing.

A method of managing heat of an electronic device on an aircraft includes transferring heat from the electronic to device to a fluid within a cavity of a body defined by at least a first wall and a second wall first wall and the electronic device in thermal communication with the first wall prior to aircraft engine start up, transitioning at least some fluid within the cavity from a liquid to a gas, producing bypass airflow, transferring heat from the fluid to the second wall and to the bypass airflow and transitioning at least some of the fluid from a gas to a liquid after engine startup. The bypass air can be fan bypass air and no bypass flow during aircraft startup. Aircraft startup can be a short-term thermal transient operation. Flowing can include passing the fluid through finned heat sink in thermal communication with the panels to accept heat therefrom during power generating mode and the flowing can be a continuous and steady state operation.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject invention appertains will readily understand how to make and use the devices and methods of the subject invention without undue experimentation, preferred embodiments thereof will be described in detail herein below with reference to certain figures, wherein:

FIG. 1 is a perspective view of a thermal management system for an electronic device array; and

FIG. 2 is a cross-section view of FIG. 1, showing the arrangement of the fins and coolant.

### DETAILED DESCRIPTION

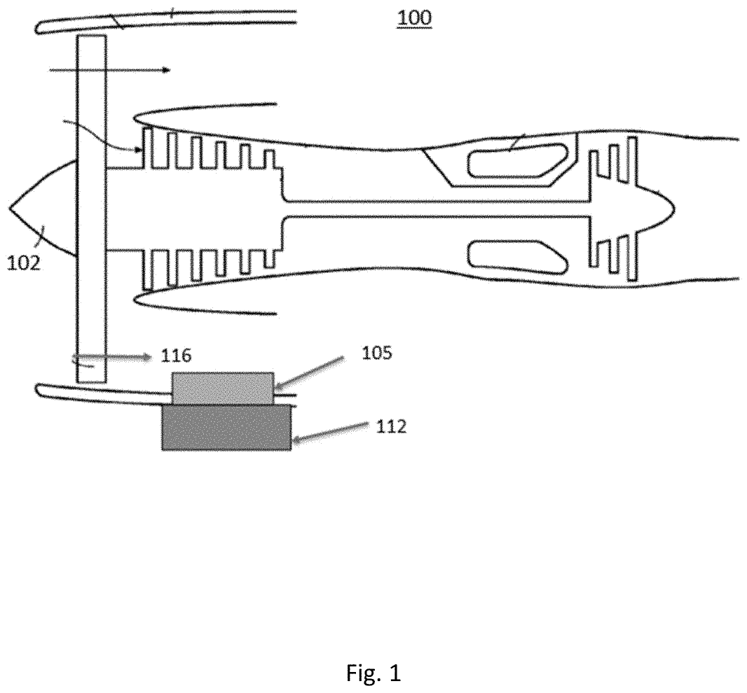

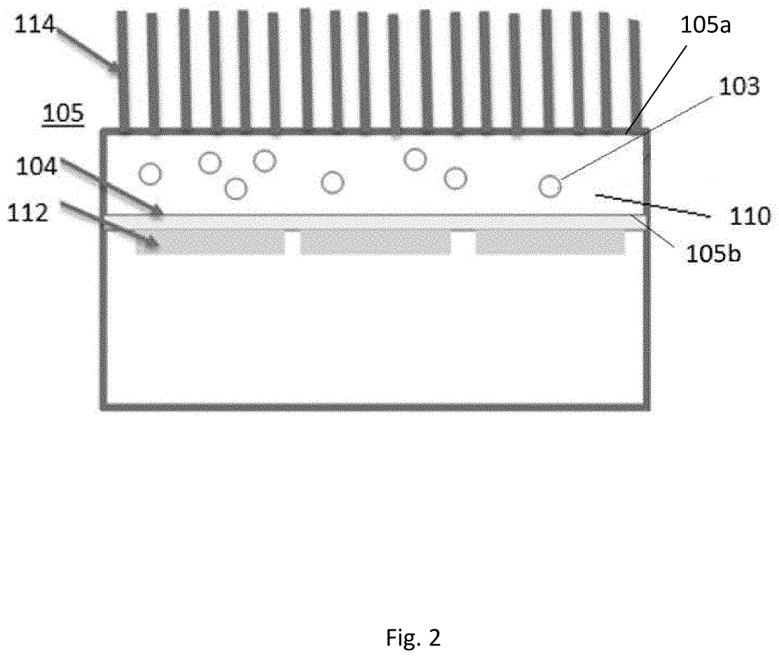

Reference will now be made to the drawings wherein like reference numerals identify similar structural features or aspects of the subject invention. For purposes of explanation and illustration, and not limitation, a partial view of an exemplary embodiment of a thermal management body in accordance with the invention is shown in FIG. 1 and is designated generally by reference character 100. Other embodiments of the thermal management body in accordance with the invention, or aspects thereof, are provided in FIG. 2, as will be described. The methods and systems of the invention can be used to provide a more compact, lighter and more efficient electronics thermal management device which provides a passive, thin and low weight compact high performance cold plate based solution for bi directional rectifier cooling. Using this cooling approach, this rectifier will be able to perform main engine start, when fan air flow 116 is not available, where DC electrical power is input to the bi-directional rectifier. Bi-directional rectifier converts DC to 3 phase AC power and supplies to the engine starter/generator.

FIG. 1 shows a system 100 within an aircraft engine 102 including a thermal management body 105 with a coolant 103 on the inside for cooling an electrical device 112. The thermal management body 105 is attached to the electrical device 112, which can be a bi-directional rectifier, or is also conceived to be attached to another electronic device.

FIG. 2 shows the thermal management body 105 having a cavity 110 defined by at least a first wall 105a and a second wall 105b. The first wall 105a is in thermal communication with electronic device 112 and the second wall 105b is in thermal communication with air flow 116 when the aircraft engine 102 is operating. A fluid or coolant 103 positioned within the cavity 110 transfers heat from the first wall 105a and the electronic device 112 to the fluid 103. During heating at least some of the fluid 103 transitions from a liquid to a gas. When cooling the liquid during engine 102 operation heat is transferred from the fluid 103 to the second wall 105b and the air flow 116 while transitioning at least some of the fluid 103 from a gas to a liquid. Coolant 103 is also enclosed by the cold plate 104. Cooling the electronic device 112 during and after aircraft start up is done by boiling a liquid material 103 within the cavity 110 adjacent to the electronic device 112, and condensing a resultant vapor of the liquid material by flowing bypass air 116 over the body 105 to remove heat from the material. The thermal management body 105 includes a cavity 110 for storing the coolant 103 and the cold plate 104 separates the cavity 110 from the electronics 112. The electronics 112 are in thermal communication with the coolant 103. A series of fins 114 are located on the outside of the thermal management body 105 and protrude into a fan bypass 116 section of the aircraft engine 102. These fins 114 are cooled by the bypass air and in turn cool the coolant 103 can be a two-phase coolant such as a NOVEC coolant. During main engine 102 start mode, the Novec coolant 103 stores heat by transient pool boiling. The heat is stored by latent heat of evaporation. Also during startup there is no main air flow 116, which is a transient short term operation. Later during generate mode, the main fan of the engine 102 provides condensation of Novec vapor and the thermal management body 105 is cooled by main fan flow 116. This cooling becomes a steady-state continuous operation

The methods and systems of the present disclosure, as described above and shown in the drawings, provide for electronics thermal management system with superior properties including increased reliability and reduced size and weight. While the apparatus and methods of the subject disclosure have been shown and described with reference to embodiments, those skilled in the art will readily appreciate that changes and/or modifications may be made thereto without departing from the spirit and score of the subject disclosure.

1-8. (canceled)

9. A method of managing heat of an electronic device on an aircraft comprising:
transferring heat from the electronic to device to a fluid within a cavity of a body defined by at least a first wall and a second wall first wall and the electronic device in thermal communication with the first wall prior to aircraft engine start up;
transitioning at least some fluid within the cavity from a liquid to a gas; producing bypass airflow; transferring heat from the fluid to the second wall and to the bypass airflow; and
transitioning at least some of the fluid from a gas to a liquid after engine startup.

10. The method of claim 9, wherein the bypass air is fan bypass air.

11. The method of claim 10, wherein there is no bypass flow during aircraft startup.

12. The method of claim 10, wherein aircraft startup is a short-term thermal transient operation.

13. The method of claim 9, wherein flowing includes passing the fluid through finned heat sink in thermal communication with the panels to accept heat therefrom during power generating mode.

14. The method of claim 13, wherein the flowing is continuous and steady state operation.
